(19) United States
(12) Patent Application Publication
(10) Pub. No.: US 2013/0135000 A1
(43) Pub. Date: May 30, 2013

(54) SEMICONDUCTOR TEST BOARD AND SEMICONDUCTOR BOARD

(71) Applicants: Kijae SONG, Paju-si (KR); Sangjin KYUNG, Cheonan-si (KR); Sang-Chol KIM, Cheonan-si (KR); Doohwan OK, Cheonan-si (KR)

(72) Inventors: Kijae SONG, Paju-si (KR); Sangjin KYUNG, Cheonan-si (KR); Sang-Chol KIM, Cheonan-si (KR); Doohwan OK, Cheonan-si (KR)

(73) Assignee: SAMSUNG ELECTRONICS CO., LTD., Suwon-si (KR)

(21) Appl. No.: 13/608,067

(22) Filed: Sep. 10, 2012

(30) Foreign Application Priority Data
Nov. 28, 2011 (KR) 1020110125072

(51) Int. Cl. G01R 31/26

(52) U.S. Cl. 324/750.05

(57) ABSTRACT

Provided is a semiconductor test board which includes a power supply, a first temperature resistive element and a second temperature resistive element configured to commonly receive power from the power supply and having resistances that varies with temperature, a first chip embedding unit configured to receive the power through the first temperature resistive element and having a first semiconductor package embedded therein, and a second chip embedding unit configured to receive the power through the second temperature resistive element and having a second semiconductor package embedded therein.

### CROSS-REFERENCE TO RELATED APPLICATIONS

This US non-provisional patent application claims priority under 35 USC §119 to Korean Patent Application No. 10-2011-0125072, filed on Nov. 28, 2011, the entirety of which is hereby incorporated by reference.

### BACKGROUND OF THE INVENTION

The present inventive concepts relate to semiconductor test boards and/or semiconductor boards.

After semiconductor package manufacturing processes are completed, a semiconductor package test is conducted. A burn-in test is a kind of semiconductor package test methods, which is designed to test a semiconductor package in less time. A burn-in test is conducted to detect failure of a semiconductor package early on by operating the semiconductor package under a stressful environment like inflicting a higher temperature above a normal operating temperature of the semiconductor package.

A burn-in test is conducted by embedding a plurality of devices under test (DUT, e.g., semiconductor package) on a test board, inserting the test board into a chamber, and applying high temperature to the DUT embedded on the test board, placed inside the chamber, and operating the DUT.

The number of devices under test (DUT) embedded on one test board is increasing to enhance the speed of a burn-in test.

With the advance in semiconductor process technologies, devices under test (DUT) are decreasing in size and pins or balls of the DUT are also decreasing in size. Moreover, a pitch between the pins or balls is decreasing.

### SUMMARY OF THE INVENTION

Example embodiments of the inventive concepts provide semiconductor test boards and/or semiconductor boards.

According to one embodiment of the inventive concepts, the semiconductor test board includes a power supply, a first temperature resistive element and a second temperature resistive element, both of which are configured to commonly receive power from the power supply and having resistances that varies with temperature, a first chip embedding unit configured to receive the power through the first temperature resistive element and the first chip embedding unit having a first semiconductor package embedded therein, and a second chip embedding unit configured to receive the power through the second temperature resistive element and having a second semiconductor package embedded therein.

At least one of the first and second temperature resistive elements may have a resistance increasing as temperature increases.

At least one of the first and second temperature resistive elements may be a positive temperature coefficient (PTC) thermistor. Each of the first and second chip embedding units may include a plurality of connection pins. The plurality of connection pins may be configured to receive a ball grid array (BGA) and receiving ends of the connection pins may have a recessed shape corresponding to a protruded shape of solder balls of a ball grid array (BGA).

The first temperature resistive element may be configured to reduce an over-current flowing to the first chip embedding unit when the connection pins of the first chip embedding unit are short-circuited to each other.

The second temperature resistive element may be configured to reduce an over-current flowing to the second chip embedding unit when the connection pins of the second chip embedding unit are short-circuited to each other.

According to another embodiment of the inventive concepts, the semiconductor board includes a power supply configured to supply power, a first chip embedding unit and a second chip embedding unit configured to commonly receive the power, the power supplied from the power supply to the first chip embedding unit along a first path, the power supplied from the power supply to the second chip embedding unit along a second path each of the first and second chip embedding units configured to have a semiconductor package embedded therein, a first element configured to reduce an over-current flowing to the first chip embedding unit based on a temperature change along the first path, and a second element configured to reduce an over-current flowing to the second chip embedding unit based on a temperature change along the second path.

The first element may be a resistor having a resistance that varies with temperature in the first path, and the second element may be a resistor having a resistance that varies with temperature in the second path.

The resistance of the first element may increase as the temperature to the first path increases, and the resistance of the second element may increases as the temperature in the second path increases.

At least one of the first element and the second element may be a positive temperature coefficient (PTC) thermistor.

According to still another embodiment of the inventive concepts, a semiconductor test board includes a power supply configured to supply power, a chip embedding unit configured to receive a semiconductor package thereon, and a variable element electrically connected between the power supply and the chip embedding unit to provide an electrical path therebetween. The variable element is configured to change the power based on a change of an environmental condition of the electrical path.

The environmental condition may be temperature.

The variable element may be a positive resistive element, a resistance of which increases as temperature increases.

The variable elements may be a positive temperature coefficient (PTC) thermistor.

The variable element may be configured to reduce an over-current flowing to the chip embedding unit based on the change of the environmental condition.

The chip embedding unit may include a plurality of connection pins, which are configured to receive a ball grid array (BGA). For example, receiving ends of the connection pins may have a recessed shape corresponding to a protruded shape of solder balls of a ball grid array (BGA).

### BRIEF DESCRIPTION OF THE DRAWINGS

Example embodiments will be more clearly understood from the following brief description taken in conjunction with the accompanying drawings. FIGS. 1-7 represent non-limiting, example embodiments as described herein.

FIG. 1 illustrates a test system according to an example embodiment of the inventive concepts.

FIG. 2 is a perspective view illustrating one of semiconductor test boards in FIG. 1 and devices under test (DUT) embedded thereon.

FIG. 3 is a cross-sectional view taken along the line III-III′ in FIG. 2.

FIG. 4 illustrates an example where a device under test (DUT) is misloaded on an embedding unit in a boxed portion A.

FIG. 5 is a block diagram illustrating an electrical configuration of a semiconductor test board according to an example embodiment of the inventive concepts.

FIG. 6 is a graphic diagram illustrating a resistance characteristic depending on temperature of temperature resistive elements.

FIG. 7 is a perspective view of a semiconductor board according to an example embodiment of the inventive concepts.

It should be noted that these figures are intended to illustrate the general characteristics of methods, structure and/or materials utilized in certain example embodiments and to supplement the written description provided below. These drawings are not, however, to scale and may not precisely reflect the precise structural or performance characteristics of any given embodiment, and should not be interpreted as defining or limiting the range of values or properties encompassed by example embodiments. For example, the relative thicknesses and positioning of molecules, layers, regions and/or structural elements may be reduced or exaggerated for clarity. The use of similar or identical reference numbers in the various drawings is intended to indicate the presence of a similar or identical element or feature.

### DETAILED DESCRIPTION

Example embodiments will now be described more fully with reference to the accompanying drawings. Example embodiments may, however, be embodied in many different forms and should not be construed as being limited to the embodiments set forth herein; rather, these embodiments are provided so that this disclosure will be thorough and complete, and will fully convey the concept of example embodiments to those of ordinary skill in the art. In the drawings, the thicknesses of layers and regions are exaggerated for clarity. Like reference numerals in the drawings denote like elements throughout, and thus their description will be omitted.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. As used herein the term “and/or” includes any and all combinations of one or more of the associated listed items. Other words used to describe the relationship between elements or layers should be interpreted in a like fashion (e.g., “between” versus “directly between,” “adjacent” versus “directly adjacent,” “on” versus “directly on”).

It will be understood that, although the terms “first”, “second”, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises”, “comprising”, “includes” and/or “including,” if used herein, specify the presence of stated features, integers, steps, operations, elements and/or components, but do not preclude the presence or addition of one or more other features, integers, steps, operations, elements, components and/or groups thereof.

Example embodiments are described herein with reference to cross-sectional illustrations that are schematic illustrations of idealized embodiments (and intermediate structures) of example embodiments. As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle may have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments. It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

Unless otherwise defined, all terms (including technical and scientific terms) used herein have the same meaning as commonly understood by one of ordinary skill in the art to which example embodiments belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

The inventive concepts will now be described more fully hereinafter with reference to the accompanying drawings.

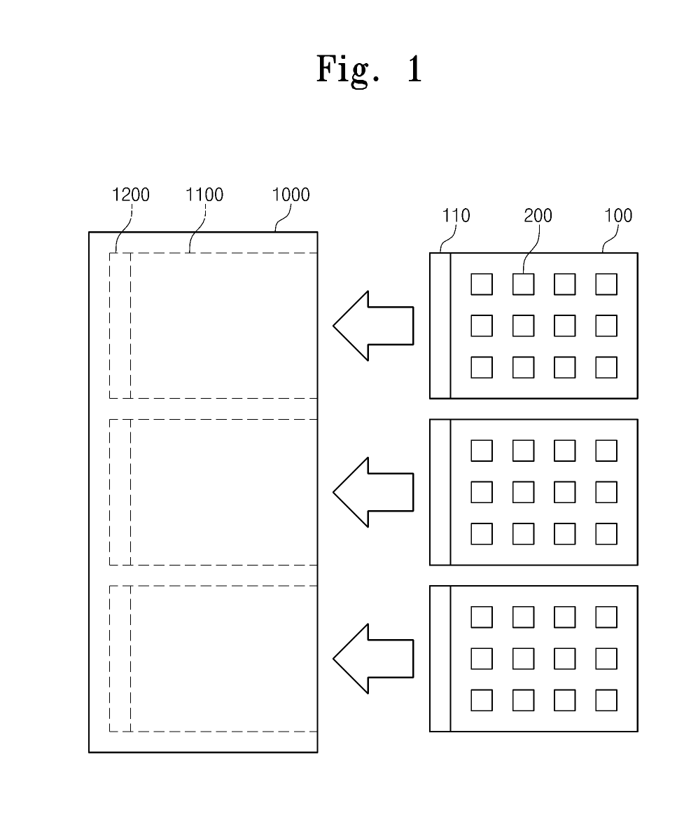

FIG. 1 illustrates a test system according to an example embodiment of the inventive concepts. As illustrated, the test system includes a plurality of semiconductor test boards 100 and a test chamber 1000.

Each of the semiconductor test boards is configured to embed devices under test (DUT) 200. The DUT may be semiconductor packages. The DUT 200 may include volatile memory packages such as static RAM (SRAM) packages, dynamic RAM (DRAM) packages, and synchronous DRAM (SDRAM) packages. The DUT 200 may include nonvolatile memory packages such as read only memory (ROM) packages, programmable ROM (PROM) packages, electrically programmable ROM (EPROM) packages, electrically erasable and programmable ROM (EEPROM) packages, flash memory packages, phase change RAM (PRAM) packages, magnetic RAM (MRAM) packages, resistive RAM (RRAM) packages, and ferroelectric RAM (FRAM) packages.

Each of the semiconductor test boards 100 may include a test board connector 110. Each of the semiconductor test boards 100 may receive a signal and a power through the connector 110. The signal and the power received through the connector 100 may be commonly provided to the DUT 200.

A plurality of insertion spaces 1100 are provided in the test chamber 1000. The insertion spaces 1100 may be spaces into which the semiconductor test boards 100 are to be inserted, respectively. In-chamber connectors 1200 connected to the test board connectors 110 may be provided on one-side surfaces of the insertion spaces, respectively. The test chamber 1000 may provide a signal and a power to the semiconductor test boards 100 through the in-chamber connectors 1200.

When the semiconductor test boards 100 are inserted, an internal temperature of the test chamber 1000 may increase to a higher temperature. For example, the internal temperature of the test chamber 1000 may increase to a higher temperature above a normal operating temperature of the DUT 200. The test chamber 1000 may provide a test signal and a power to the semiconductor test boards 100 through the in-chamber connectors 1200 while increasing its internal temperature, thereby the test chamber 1000 may conduct a burn-in test for the DUT 200.

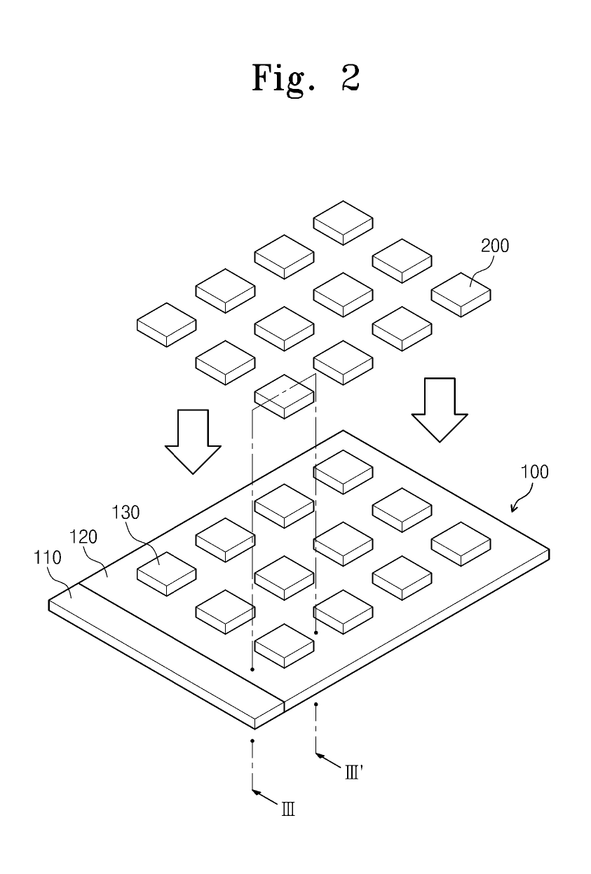

FIG. 2 is a perspective view illustrating one of semiconductor test boards 100 in FIG. 1 and DUT 200 embedded thereon. As illustrated, the semiconductor test board 100 includes a test board connector 110, a body 120, and embedding units 130.

The test board connector 110 may include conductive lines provided at one side surface of the body 120, a top surface of one side of the body 120 or a bottom surface of one side of the body 120.

The body 120 may include a printed circuit board (PCB). The body 120 may include interconnections electrically connecting the test board connector 110 to the embedding units 130. The body 120 may be provided with various elements such as a resistor, a capacitor, and an inductor.

Devices under test (DUT, e.g., semiconductor packages) 200 may be embedded on the embedding units 130.

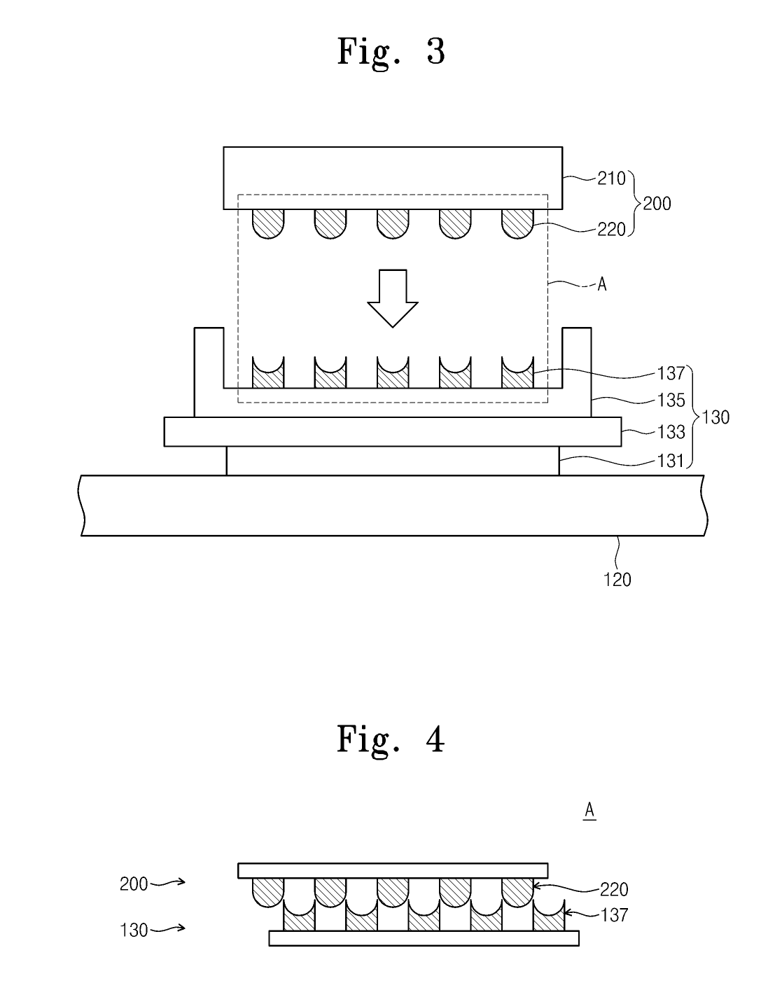

FIG. 3 is a cross-sectional view taken along the line III-III′ in FIG. 2. Referring to FIGS. 2 and 3, the embedding unit 130 is provided on the body 120. The embedding unit 130 includes a connector part 131, a package board 133, a socket 135, and connection pins 137.

The connector part 131 may electrically connect the interconnections of the body 120 to interconnections of the package board 133. The package board 133 may be a board on which at least one DUT 200 is embedded. The package board 133 may be a printed circuit board (PCB). The socket 135 may receive the DUT 200 to be embedded on the package board 133. For example, the connection pins on the socket 135 may receive the DUT 200.

A device under test (DUT) 200 may include a body 210 and a connection portion 220.

The connection pins 137 may have a structure corresponding to the connection portion 220 of the DUT 200. For example, when the DUT 200 includes solder balls as the connection portion 220, the connection pins 137 may be disposed at the same position as the solder balls 220 and have a structure concavely recessed toward the bottom of the socket 135. For example, top surfaces of the connection pins 137 may be recessed toward bottom surfaces such that the recessed shape corresponds to a protruded shape of the solder balls 220 to be coupled.

FIG. 4 illustrates an example where a device under test (DUT) is misloaded on an embedding unit in a boxed portion A. Referring to FIG. 4, when the DUT 200 is misloaded on the embedding unit 130, adjacent connection pins 137 of the embedding unit 130 may be short-circuited to each other by the solder balls 220. For example, if a connection pin supplying a power VCC to the DUT 200 and a connection pin supplying a ground voltage GND are short-circuited to each other, a condition enabling over-current to flow to the embedding unit 130 may be established. The over-current may induce a stress to the embedding unit 130, the DUT 200, and the semiconductor test board 100 and accelerate degradation of the embedding unit 130, the DUT 200, and the semiconductor test board 100.

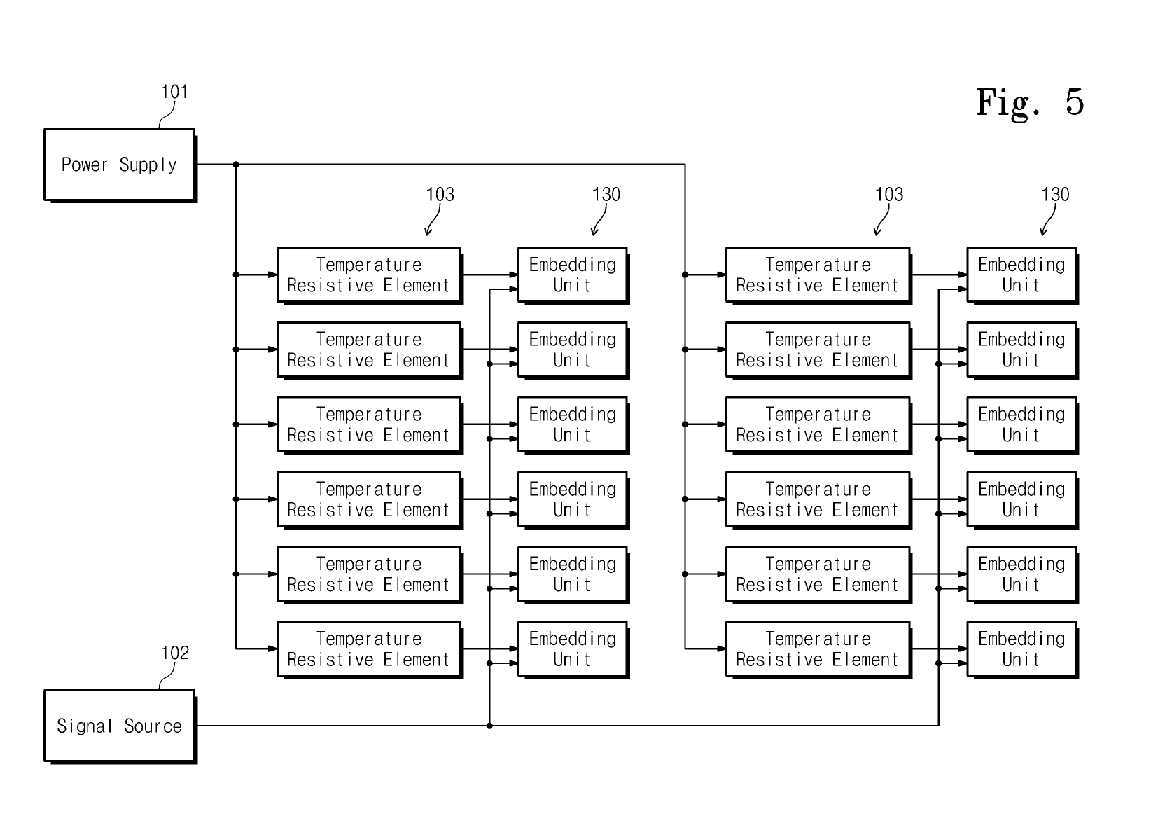

FIG. 5 is a block diagram illustrating an electrical configuration of a semiconductor test board 100 according to an example embodiment of the inventive concepts. As illustrated, the semiconductor test board 100 may include a power supply 101, a signal source 102, a plurality of temperature resistive elements 103, and a plurality of embedding units 130.

Devices under test (DUT) 200 may be embedded on the embedding units 130.

The power supply 101 may supply power to the respective embedding units 130 through the temperature resistive elements 103. The signal source 102 may supply a signal to the respective embedding units 130. The power supply 101 and the signal source 102 may receive power and signal from the test board connector 110 in FIG. 2 and transfer the received power and signal to the embedding units 130.

The temperature resistive elements 103 may have resistances varying with temperature. For example, the temperature resistive elements 103 may have higher resistances as temperature increases. Each of the temperature resistive elements 103 may be a positive temperature coefficient (PTC) thermistor.

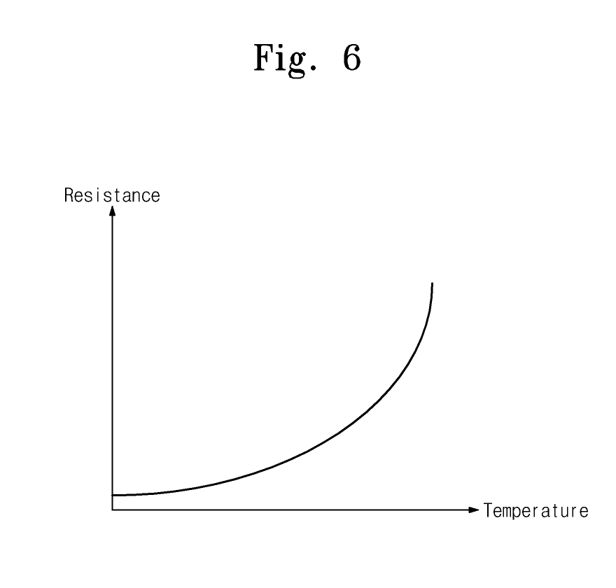

FIG. 6 is a graphic diagram illustrating a resistance characteristic of temperature resistance elements 103 with varying temperature. In the graph in FIG. 6, a horizontal axis represents temperature and a vertical axis represents resistance.

Referring to FIGS. 5 and 6, when the amount of current supplied to any one of the embedding units 130 increases, temperature of a path along which the current flows (a path including the temperature resistive element 103) increases. As the temperature increases, resistance of the temperature resistive element 103 increases. If the resistance of the temperature resistive element 103 increases, the amount of current capable of flowing along the path including the temperature resistive element 103 decreases. If temperature resistive elements 103 having resistances increasing with the increase in temperature are provided between the power supply 101 and the embedding units 130, the temperature resistive elements 103 may prevent or reduce over-current from flowing to the embedding units 130. Accordingly, a resistance of each of the temperature resistive elements 103 may change respectively depending on current supplied to each of the embedding units 130 and prevent or reduce over-currents from flowing to the each of the embedding units 130.

A resistor formed on a current flow path causes a voltage drop. An operating voltage margin of semiconductor packages manufactured to operate under a low-power environment (e.g., swing width of a voltage allowing a normal operation of semiconductor packages) is smaller than that of conventional semiconductor packages. Hence, if the voltage drop is caused by the resistor, devices under test (DUT) 200 may not be normally tested.

According to example embodiments of the inventive concepts, when the amount of current flowing through the temperature resistive elements 103 is within a normal range, the temperature resistive elements 103 may have a lower resistance. Thus, when normal current is supplied to the embedding units 130, the drop of a voltage supplied to the embedding units 130 may be minimized.

The temperature resistive elements 103 may comprise passive elements such as thermistors. If the temperature resistive elements 103 comprise passive elements, an area occupied by the temperature resistive elements 103 may be reduced. Thus, an area occupied by the temperature resistive elements 103 in the test board 100 may be reduced and a greater number of devices under test (DUT) 200 may be embedded on the test board 100.

Exemplary embodiments of the inventive concepts have been described with reference to the test board 100 for a burn-in test. However, the inventive concepts are not limited to the test board 100 for a burn-in test. The inventive concepts may be applied to semiconductor boards with a socket from which a semiconductor package may be removed.

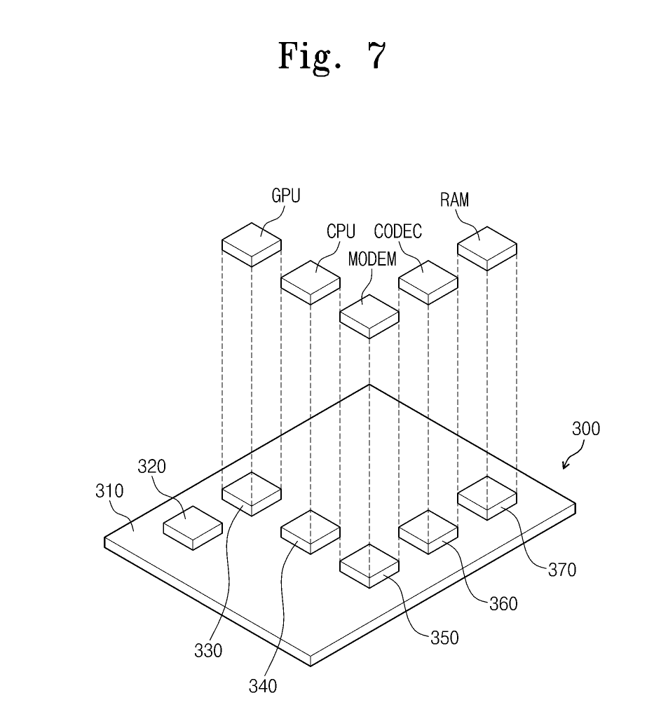

FIG. 7 is a perspective view of a semiconductor board 300 according to an example embodiment of the inventive concepts. As illustrated, the semiconductor board 300 includes a body 310, a power supply 320, and a plurality of sockets 330-370.

The body 310 may be a printed circuit board (PCB).

The power supply 320 may supply power to the semiconductor board 300 including the sockets 330-370.

Removable semiconductor packages may be inserted into the sockets 330-370. For example, a graphic processing unit (GPU) package, a central processing unit (CPU) package, a modem package, a codec package, and a RAM package may be inserted into the sockets 330-370.

Temperature resistive elements may be provided between the sockets 330-370 and the power supply 320. The temperature resistive elements may prevent or reduce over-current which may flow when semiconductor packages are mistakenly coupled to the sockets 330-370.

According to the inventive concepts described so far, the temperature resistive element having resistance varying with temperature is provided between a power supply and an embedding unit on which a device under test (DUT) is embedded. When the amount of current supplied to the embedding unit increases, the resistance of the temperature resistive element increases. Thus, there are provided a semiconductor test board and a semiconductor board which prevent over-current from flowing to the embedding unit and have improved reliability.

While the inventive concepts have been particularly shown and described with reference to exemplary embodiments thereof, it will be apparent to those of ordinary skill in the art that various changes in form and detail may be made therein without departing from the spirit and scope of the inventive concepts as defined by the following claims.

What is claimed is:

1. A semiconductor test board comprising:
a power supply;
a first temperature resistive element and a second temperature resistive element, both configured to commonly receive power from the power supply and having resistances that vary with temperature;
a first chip embedding unit configured to receive the power through the first temperature resistive element, the first chip embedding unit having a first semiconductor package embedded therein; and
a second chip embedding unit configured to receive the power through the second temperature resistive element, the second chip embedding unit having a second semiconductor package embedded therein.

2. The semiconductor test board of claim 1, wherein at least one of the first and second temperature resistive elements has a resistance increasing as temperature increases.

3. The semiconductor test board of claim 1, wherein at least one of the first and second temperature resistive elements is a positive temperature coefficient (PTC) thermistor.

4. The semiconductor test board of claim 1, wherein each of the first and second chip embedding units includes a plurality of connection pins, the plurality of connection pins configured to receive a ball grid array (BGA), and receiving ends of the connection pins having a recessed shape corresponding to a protruded shape of solder balls of the ball grid array (BGA).

5. The semiconductor test board of claim 4, wherein the first temperature resistive element is configured to reduce an over-current flowing to the first chip embedding unit when the connection pins of the first chip embedding unit are short-circuited to each other.

6. The semiconductor test board of claim 4, wherein the second temperature resistive element is configured to reduce an over-current flowing to the second chip embedding unit when the connection pins of the second chip embedding unit are short-circuited to each other.

7. A semiconductor board comprising:
a power supply configured to supply power;
a first chip embedding unit and a second chip embedding unit configured to commonly receive the power, the power supplied from the power supply to the first chip embedding unit along a first path, the power supplied from the power supply to the second chip embedding unit along a second path, each of the first and second chip embedding units configured to have a semiconductor package embedded therein;
a first element configured to reduce an over-current flowing to the first chip embedding unit based on a temperature change along the first path; and
a second element configured to reduce an over-current flowing to the second chip embedding unit based on a temperature change along the second path.

8. The semiconductor board of claim 7, wherein the first element is a resistor having a resistance that varies with temperature in the first path, and
wherein the second element is a resistor that varies with temperature in the second path.

9. The semiconductor board of claim 8, wherein the resistance of the first element increases as the temperature in the first path increases, and
wherein the resistance of the second element increases as the temperature in the second path increases.

10. The semiconductor board of claim 7, wherein at least one of the first element and the second element is a positive temperature coefficient (PTC) thermistor.

11. A semiconductor test board comprising:
a power supply configured to supply power;
a chip embedding unit configured to receive a semiconductor package thereon; and
a variable element electrically connected between the power supply and the chip embedding unit to provide an electrical path therebetween, the variable element configured to change the power based on a change of an environmental condition of the electrical path.

12. The semiconductor test board of claim 11, wherein the environmental condition is temperature.

13. The semiconductor test board of claim 11, wherein the variable element is a positive resistive element, a resistance of the variable element increasing as temperature increases.

14. The semiconductor test board of claim 11, wherein the variable elements is a positive temperature coefficient (PTC) thermistor.

15. The semiconductor test board of claim 11, wherein the variable element is configured to reduce an over-current flowing to the chip embedding unit based on the change of the environmental condition.

16. The semiconductor test board of claim 11, wherein the chip embedding unit includes a plurality of connection pins, the plurality of connection pins configured to receive a ball grid array (BGA), and receiving ends of the connection pins having a recessed shape corresponding to a protruded shape of solder balls of the ball grid array (BGA).
